(19) United States
(12) Patent Application Publication
(10) Pub. No.: US 2026/0231780 A1
(43) Pub. Date: Aug. 6, 2026

(54) MANUFACTURING METHOD OF ELECTRONIC DEVICE

(71) Applicant: InnoLux Corporation, Miao-Li County (TW)

(72) Inventor: Kuang-Ming FAN, Miao-Li County (TW)

(73) Assignee: InnoLux Corporation, Miao-Li County (TW)

(21) Appl. No.: 19/426,091

(22) Filed: Dec. 19, 2025

Related U.S. Application Data
(60) Provisional application No. 63/753,954, filed on Feb. 5, 2025.

(30) Foreign Application Priority Data
Sep. 25, 2025 (CN) 202511377439.0

(51) Int. Cl. H10W 70/05; G01N 21/41; H05K 3/00

(52) U.S. Cl. CPC H10W 70/095; G01N 21/41; H05K 3/0029; H05K 2203/163

(57) ABSTRACT

A manufacturing method of an electronic device includes: providing a substrate; performing a laser modification step on the substrate to form modified regions; performing a first inspection step on the substrate by a first equipment, the first inspection step including providing a first light to pass through the substrate, so as to obtain a first phase difference and calculate a first stress value; performing a perforation step on the substrate to form through holes in the modified regions; and performing a second inspection step on the substrate by the first equipment, the second inspection step including providing a second light to pass through the substrate, so as to obtain a second phase difference and calculate a second stress value. The substrate has a first temperature during the first inspection step, and the substrate has a second temperature different from the first temperature during the second inspection step.

### CROSS REFERENCE TO RELATED APPLICATION

This application claims the benefit of U.S. Provisional Application No. 63/753,954, filed on Feb. 5, 2025. The content of the application is incorporated herein by reference.

### BACKGROUND OF THE DISCLOSURE

### 1. Field of the Disclosure

The present disclosure relates to a manufacturing method of an electronic device, and more particularly to a manufacturing method of an electronic device including a step of detecting a stress value of a substrate.

### 2. Description of the Prior Art

With the advancement of semiconductor packaging technology, electronic products are increasingly designed to be lightweight, compact, and feature high circuit density. A substrate structure with a through hole formed in a substrate and a conductive material disposed therein for transmitting electrical signals has gradually become one of the popular options for high-density interconnect packaging technology. During manufacturing products with the aforementioned substrate structure, failure to promptly perform quality control using a stress measurement system may result in reduced product yield and increased cost loss.

### SUMMARY OF THE DISCLOSURE

One of objectives of the present disclosure is to provide a manufacturing method of an electronic device. By respectively inspecting the substrate after a laser modification step and a perforation step, the stress value of the substrate may be obtained in real time for quality control, thereby improving product yield. Furthermore, before performing inspection on the substrate, the substrate may be heated to a specific temperature, so that the stress value of the substrate at the specific temperature may be detected.

An embodiment of the present disclosure provides a manufacturing method of an electronic device. The method includes: providing a substrate; performing a laser modification step on the substrate to form a plurality of modified regions; performing a first inspection step on the substrate by a first equipment after the laser modification step, wherein the first inspection step includes providing a first light to pass through the substrate, so as to obtain a first phase difference and calculate a first stress value; performing a perforation step on the substrate to form a plurality of through holes in the plurality of modified regions; and performing a second inspection step on the substrate by the first equipment after the perforation step, wherein the second inspection step includes providing a second light to pass through the substrate, so as to obtain a second phase difference and calculate a second stress value. The substrate has a first temperature during the first inspection step, the substrate has a second temperature during the second inspection step, and the second temperature is different from the first temperature.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2 to FIG. 4 are schematic diagrams illustrating a portion of the process of a manufacturing method of an electronic device according to an embodiment of the present disclosure.

FIG. 5 is a temperature rise profile diagram of various embodiments for heating a substrate by a first equipment according to the present disclosure.

FIG. 6 is a schematic diagram illustrating the architecture of a first equipment according to another embodiment of the present disclosure.

FIG. 7 is a schematic diagram illustrating the architecture of a first equipment according to yet another embodiment of the present disclosure.

FIG. 8 is a schematic diagram illustrating the architecture of a first equipment according to still another embodiment of the present disclosure.

FIG. 9 is a cross-sectional schematic diagram of an electronic device according to an embodiment of the present disclosure.

FIG. 10 is a cross-sectional schematic diagram of an electronic device according to another embodiment of the present disclosure.

### DETAILED DESCRIPTION

In the present disclosure, various drawings show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in the present disclosure, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in the present disclosure generally mean being within 20% of a given value or range, or being within 10% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may applied to a high-speed computing module, a power module, a semiconductor package device, a display device, a light-emitting device, a backlight device, an antenna device, a sensing device, a tiled device or other suitable devices, but not limited herein. The electronic device may include electronic elements such as semiconductor elements. The semiconductor elements may include passive elements and active elements, such as capacitors, resistors, inductors, diodes, transistors, integrated circuits, etc. The semiconductor element may include a semiconductor layer or an electronic element manufactured by a semiconductor process. The electronic device may include peripheral systems such as a driving system, a controlling system, a light source system, a shelving system, and the like.

The manufacturing method of the electronic device of the present disclosure may for example be applied to a wafer-level package (WLP) process or a panel-level package (PLP) process, wherein the WLP process or the PLP process may include a chip-first process or a chip-last process, but not limited herein. The electronic device may include the system on a chip (SoC), system in a package (SiP), antenna in package (AiP), co-packaged optics (CPO) or combinations of the above devices, but not limited herein.

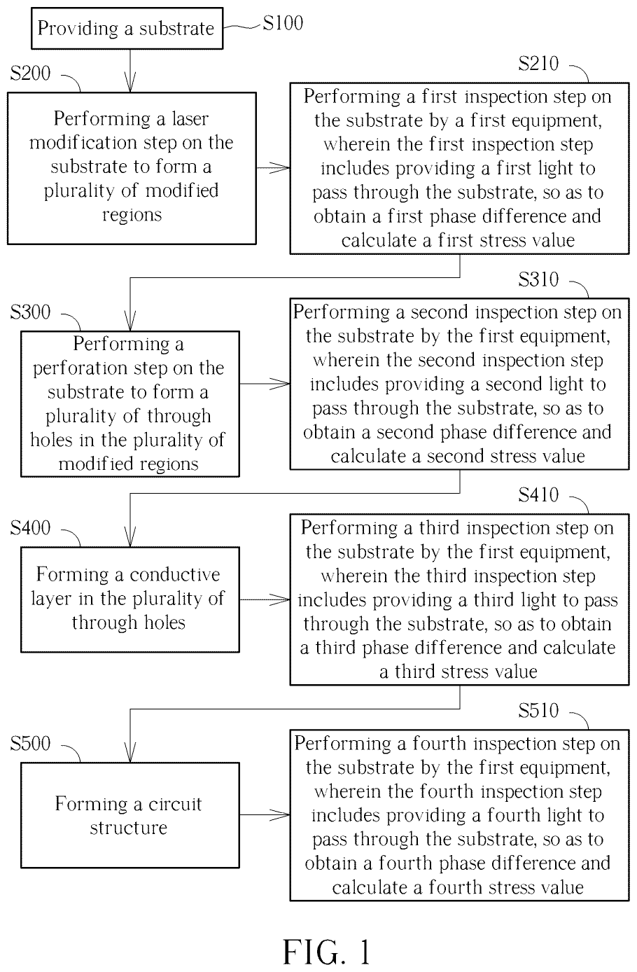

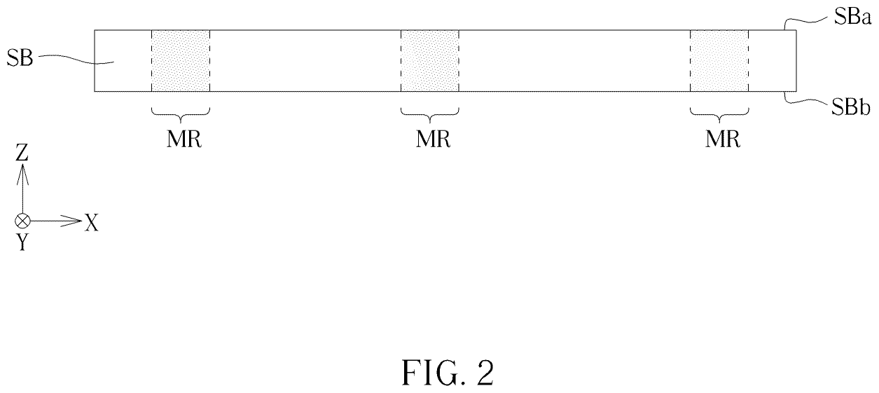

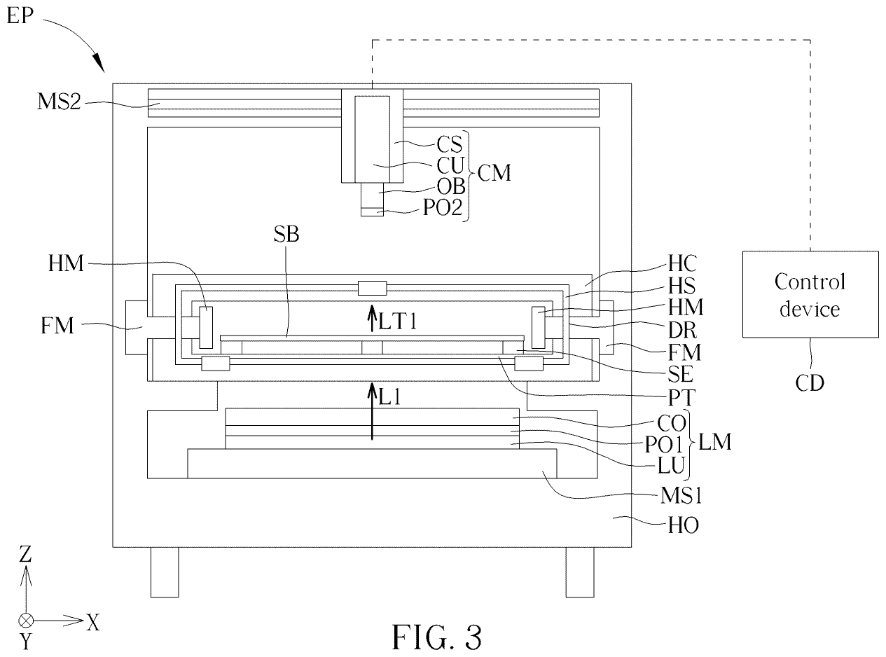

Please refer to FIG. 1 and FIG. 2 to FIG. 4. FIG. 1 is a flowchart of a manufacturing method of an electronic device according to an embodiment of the present disclosure. FIG. 2 to FIG. 4 are schematic diagrams illustrating a portion of the process of a manufacturing method of an electronic device according to an embodiment of the present disclosure, wherein FIG. 3 illustrates a schematic diagram showing a substrate SB placed inside a first equipment EP according to an embodiment of the present disclosure. As shown in FIG. 1, a manufacturing method of an electronic device according to an embodiment of the present disclosure may include Step S100, Step S200, Step S210, Step S300 and Step S310, and the manufacturing method of the electronic device of the present disclosure may further include other steps before, after or during any of the above steps. As shown in FIG. 1, in some embodiments, the method may further include Step S400, Step S410, Step S500 and/or Step S510. The details of each step in the manufacturing method of the electronic device according to the present disclosure will be described below with reference to FIG. 2 to FIG. 4.

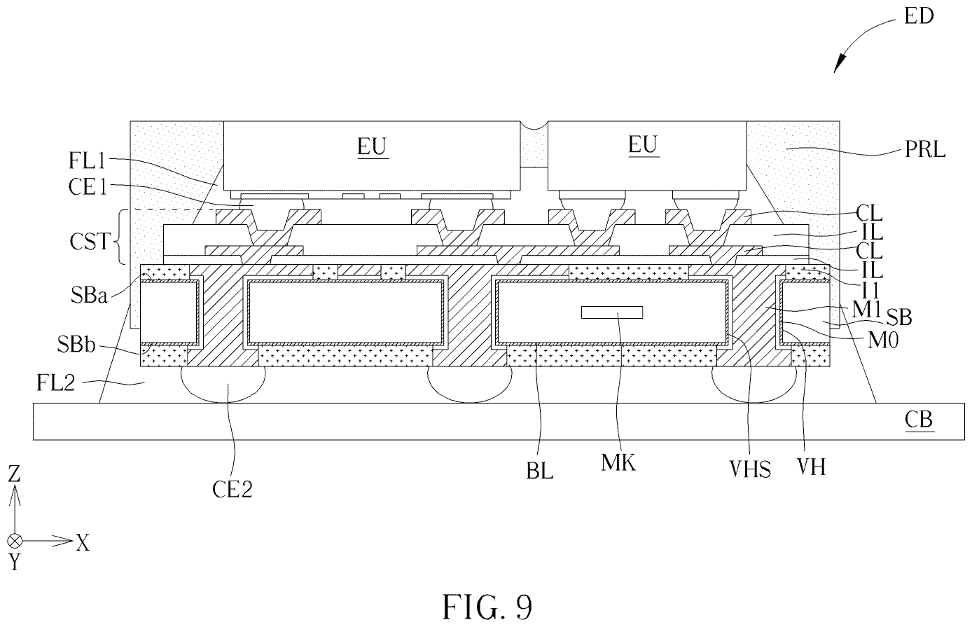

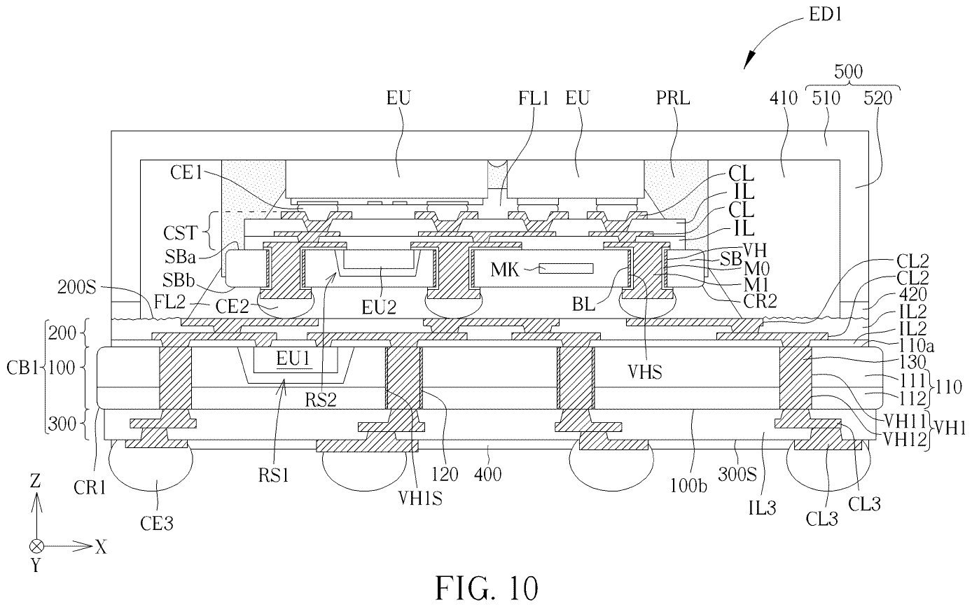

As shown in FIG. 2, Step S100 may first be performed to provide a substrate SB, wherein the substrate SB has an upper surface SBa and a lower surface SBb opposite to the upper surface SBa. The substrate SB may include a glass substrate, a transparent material including silicon, a semiconductor structure substrate, combinations of the above or other transparent materials, and the substrate SB may have certain stiffness and insulation. That is to say, the stiffness of the substrate SB may be greater than the stiffness of a circuit structure (such as a circuit structure CST shown in FIG. 9 or FIG. 10) formed on the substrate SB, for example, the stiffness of the substrate SB is greater than the stiffness of an insulating layer of the circuit structure, so that the warpage may be mitigated when the substrate SB is used for carrying the circuit structure. The warpage of the substrate SB may be, for example, less than or equal to 100 micrometers (μm), less than or equal to 30 μm, or less than or equal to 10 μm, but not limited herein. The “stiffness” referred to in the present disclosure may be tested by a universal testing machine (UTM). In some embodiments, the thermal expansion coefficient of the substrate SB may be greater than or equal to 1 ppm/° C. and less than or equal to 10 ppm/° C., thereby improving the support of the substrate SB or further improving the reliability of the electronic device. In some embodiments, the transmittance of the substrate SB for visible light may be at least greater than or equal to 80%. In some embodiments, the thickness of the substrate SB may range from 100 μm to 2000 μm.

After Step S100, Step S200 may be performed, in which a laser beam may be used to perform a laser modification step on the substrate SB to form a plurality of modified regions MR (represented by dotted shading in FIG. 2). The bonding capability of the modified regions MR formed by laser modification is different from that of the unmodified regions. That is, the structure of the modified regions MR is weakened, or the refractive index of the modified regions MR for light is different from that of the unmodified regions.

As shown in FIG. 3, then Step S210 is performed to conduct a first inspection step on the substrate SB by a first equipment EP, wherein the first inspection step includes providing a first light L1 to pass through the substrate SB, so as to obtain a first phase difference and calculate a first stress value. During the first inspection step, the substrate SB has a first temperature. Specifically, the first inspection step (i.e., Step S210) may include the following steps: before providing the first light L1, the substrate SB may be placed on a platform PT of the first equipment EP and heated to the first temperature. In some embodiments, the first equipment EP may monitor whether the temperature of the substrate SB reaches the first temperature, for example, by using a thermal sensor to detect and confirm the temperature of the substrate SB. When the temperature of the substrate SB reaches the first temperature, the first light L1 may be provided to pass through the substrate SB for stress detection or defect detection, such as inspection performed by photoelastic stress analysis. Taking stress detection as an example, when the substrate SB has the first temperature, the first equipment EP may provide the first light L1, and the first light L1 is enabled to pass through a first polarizer PO1 and then through the substrate SB to form a first inspection light LT1. The first inspection light LT1 may then pass through a second polarizer PO2. Accordingly, the difference generated by two orthogonal polarized lights incident simultaneously may be used to obtain the retardation and calculate the first phase difference. The phase difference is proportional to the stress value and may conform to the following equation (1), wherein P is the phase difference, X is the wavelength of the light, C is the optical stress coefficient, d is the sample thickness, and S is the stress value.

$$P = \frac{2 π}{λ} \times C \times d \times S \qquad ( 1 )$$

Accordingly, in the first inspection step, after obtaining the first phase difference, the first stress value may be calculated according to the aforementioned equation (1) based on the wavelength of the first inspection light LT1 and the thickness of the substrate SB.

According to the embodiment shown in FIG. 3, the first equipment EP may include a heating chamber HC, a light-emitting module LM and a camera module CM. The light-emitting module LM and the camera module CM are disposed on two opposite sides of the heating chamber HC. The light-emitting module LM may include the first polarizer PO1, and the camera module CM may include the second polarizer PO2. The first equipment EP of this embodiment may further include, for example, a ceramic heating plate module HM and a fan module FM for heating. The ceramic heating plate module HM may heat the substrate SB to a temperature ranging from 25° C. to 500° C., but not limited herein. As shown in FIG. 3, the first inspection step (i.e., Step S210) may include the following steps: the substrate SB may be placed in the heating chamber HC, wherein the bottom of the heating chamber HC may serve as the platform PT for supporting the substrate SB, and the substrate SB is heated to the first temperature by the ceramic heating plate module HM and the fan module FM. Then, a light-emitting unit LU of the light-emitting module LM is enabled to provide the first light L1 such that the first light L1 passes through the first polarizer PO1 of the light-emitting module LM and then through the substrate SB to form the first inspection light LT1. Subsequently, the first inspection light LT1 is received by the camera module CM and passes through the second polarizer PO2 of the camera module CM. The camera module CM may be connected to a control device CD. The control device CD may calculate the first phase difference based on the first inspection light LT1 received by the camera module CM, and further calculate the first stress value according to the equation (1). In some embodiments, the control device CD may compare the first stress value with an inspection criterion to determine whether the first stress value is normal or abnormal. If the first stress value is determined to be normal, subsequent process steps (e.g., Step S300) may be performed. If the first stress value is determined to be abnormal, a rework and repair process may be performed on the substrate SB, or the substrate SB may be scrapped. The light-emitting module LM may further include a diffuser and a collimator disposed between the light-emitting unit LU and the first polarizer PO1.

The control device CD may include a processing unit, a memory, or other suitable components. The first light L1 may be visible light having a wavelength of 360 nanometers (nm) to 830 nm, near-infrared light having a wavelength of 700 nm to 1400 nm, short-wave infrared light having a wavelength of 1400 nm to 3000 nm, mid-wave infrared light having a wavelength of 3000 nm to 5000 nm, or long-wave infrared light having a wavelength of 8 μm to 12 μm, and a camera CU of the camera module CM may be configured to receive any one of the aforementioned types of light.

In some embodiments, before performing Step S210, an environmental calibration step may be conducted. For example, the environmental calibration step may include detecting a value obtained by allowing light to pass through the heating chamber HC when the substrate SB is not placed therein. The control device CD may use this value as a reference point for calibration in subsequent inspection steps. In some embodiments, the refractive index of the heating chamber HC may be greater than or equal to 1.4 and less than or equal to 1.6, or greater than or equal to 1.48 and less than or equal to 1.53, so as to reduce the influence on the light passing through the heating chamber HC, thereby improving the accuracy of inspection. In some embodiments, the refractive index of the heating chamber HC may be equal to the refractive index of the substrate SB, so as to improve the accuracy of inspection.

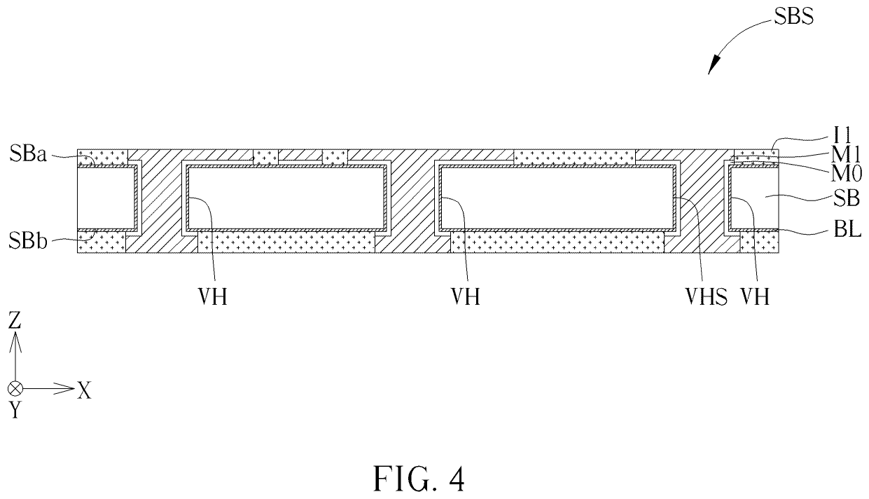

As shown in FIG. 4, then Step S300 is performed to conduct a perforation step on the substrate SB to form a plurality of through holes VH in the plurality of modified regions MR. Each through hole VH may penetrate the substrate SB, and a side wall VHS of the through hole VH may be connected to the upper surface SBa and the lower surface SBb of the substrate SB respectively. After Step S300, Step S310 may be performed to conduct a second inspection step on the substrate SB by the first equipment EP shown in FIG. 3. The second inspection step includes providing a second light to pass through the substrate SB, so as to obtain a second phase difference and calculate a second stress value. During the second inspection step, the substrate SB has a second temperature, and the second temperature is different from the first temperature. The wavelength of the second light may be referred to the wavelength of the first light L1 described above, and the wavelength of the second light may be the same as or different from the wavelength of the first light L1. Specifically, the second inspection step (i.e., Step S310) may include the following steps: before providing the second light, the substrate SB may be placed on the platform PT of the first equipment EP and heated to the second temperature. In some embodiments, the first equipment EP may monitor whether the temperature of the substrate SB reaches the second temperature. When the temperature of the substrate SB reaches the second temperature, the second light may be provided to pass through the substrate SB for stress detection or defect detection. Taking stress detection as an example, when the substrate SB has the second temperature, the first equipment EP may provide the second light, and the second light is enabled to pass through the first polarizer PO1 and then through the substrate SB to form a second inspection light. The second inspection light may then pass through the second polarizer PO2. Accordingly, the difference generated by two orthogonal polarized lights incident simultaneously may be used to obtain the retardation and calculate the second phase difference. In the second inspection step, after obtaining the second phase difference, the second stress value may be calculated according to the aforementioned equation (1) based on the wavelength of the second inspection light and the thickness of the substrate SB.

According to the first equipment EP shown in FIG. 3, Step S310 may include the following steps: the substrate SB may be placed in the heating chamber HC, wherein the bottom of the heating chamber HC may serve as the platform PT for supporting the substrate SB, and the substrate SB is heated to the second temperature by the ceramic heating plate module HM and the fan module FM. Then, the light-emitting unit LU of the light-emitting module LM is enabled to provide the second light such that the second light passes through the first polarizer PO1 of the light-emitting module LM and then through the substrate SB to form the second inspection light. Subsequently, the second inspection light is received by the camera module CM and passes through the second polarizer PO2 of the camera module CM. The control device CD may calculate the second phase difference based on the second inspection light received by the camera module CM, and further calculate the second stress value according to the aforementioned equation (1). In some embodiments, the control device CD may compare the second stress value with an inspection criterion to determine whether the second stress value is normal or abnormal. If the second stress is determined to be normal, subsequent process steps may be performed. If the second stress is determined to be abnormal, a rework or repair process may be performed, or the substrate SB may be scrapped.

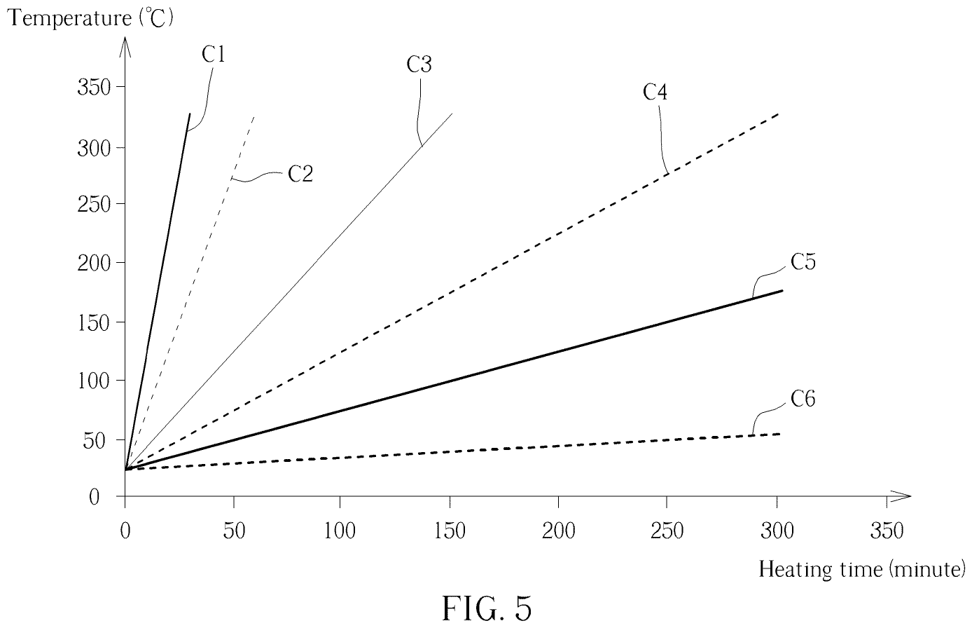

Please refer to FIG. 5, which is a temperature rise profile diagram of various embodiments for heating a substrate by a first equipment according to the present disclosure, wherein the horizontal axis represents heating time (in minutes), and the vertical axis represents temperature (in ° C.). As shown in FIG. 5, the heating rate of the substrate SB placed in the heating chamber HC may range from 0.1° C. per minute to 10° C. per minute (i.e., 0.1° C./min to 10° C./min). For example, any one of the temperature rise profiles C1 to C6 may be adopted, wherein the heating rate of the temperature rise profile C1 is 10° C. per minute, and the heating rate of the temperature rise profile C6 is 0.1° C. per minute. In some embodiments, during the first inspection step (i.e., Step S210) and the second inspection step (i.e., Step S310), the substrate SB may be heated to the first temperature and the second temperature according to any one of the temperature rise profiles shown in FIG. 5.

According to the embodiment shown in FIG. 3, the first equipment EP may further include a housing HO and a first moving module MS1. The first moving module MS1 is disposed on the housing HO and may be connected to the heating chamber HC and the light-emitting module LM, so that the heating chamber HC and the light-emitting module LM are movable along a direction X (also referred to as a first direction). That is to say, since the bottom of the heating chamber HC serves as the platform PT for carrying the substrate SB, the platform PT is movable along the direction X, thereby allowing the substrate SB as the object to be inspected to move accordingly, and the light-emitting module LM together with the heating chamber HC may be moved by the first moving module MS1 along the direction X. In this embodiment, the first equipment EP may further include a second moving module MS2 connected to the camera module CM, so that the camera module CM is movable along a direction Y (also referred to as a second direction). The direction X and the direction Y are respectively perpendicular to a direction Z, and the direction Y is perpendicular to the direction X. The direction Z may be a normal direction of the substrate SB or a normal direction of the manufactured circuit structure CST. As shown in FIG. 3, the light-emitting module LM may include the light-emitting unit LU, the first polarizer PO1, and a protective layer CO. The first polarizer PO1 is disposed on the light-emitting unit LU, and the protective layer CO is disposed on the first polarizer PO1, but not limited herein. The camera module CM may include the camera CU, an objective lens OB, the second polarizer PO2, and a camera cooling system CS. The objective lens OB may be disposed between the camera CU and the second polarizer PO2, and the camera cooling system CS may be disposed around the camera CU. The heating chamber HC may have a chamber door DR, which may be opened and closed to facilitate placement of the substrate SB, and a heat-resistant adhesive HS may be disposed at the edge of the chamber door DR. In some embodiments, a plurality of support elements SE may be disposed on the bottom of the heating chamber HC (i.e., the platform PT), and the substrate SB may be placed on the support elements SE. The material of the support elements SE may include quartz, but not limited herein. According to some embodiments, multiple first equipment EP may be connected in series, and the object to be inspected may be transferred to multiple light-emitting modules LM for inspection via carrying by the platform PT, thereby achieving inspection under different conditions without flipping the object to be inspected and reducing production cost.

According to the embodiment shown in FIG. 4, then Step S400 is performed to form a conductive layer M1 in the plurality of through holes VH. For example, the conductive layer M1 may be formed in the plurality of through holes VH by electroplating, electroless plating, sputtering, or other suitable processes. The material of the conductive layer M1 may include, for example, copper (Cu), titanium (Ti), aluminum (Al), molybdenum (Mo), nickel (Ni), ruthenium (Ru), tantalum (Ta), tungsten (W), other suitable conductive materials, or combinations of the above material. Then, Step S410 is performed to conduct a third inspection step on the substrate SB by the first equipment EP shown in FIG. 3. The third inspection step may include providing a third light to pass through the substrate SB and/or the conductive layer M1, so as to obtain a third phase difference and calculate a third stress value. During the third inspection step, the substrate SB and the stacked layer structure formed thereon may have a third temperature, and the third temperature may be different from the first temperature and the second temperature. The wavelength of the third light may be the same as or different from the wavelengths of the first light L1 and the second light. The detailed steps of the third inspection step may be referred to the aforementioned first inspection step and second inspection step, and will not be repeated herein.

According to the embodiment shown in FIG. 4, before forming the conductive layer M1 (i.e., before performing Step S400), a buffer layer BL and a seed layer M0 may be formed on the side walls VHS of the through holes VH and on the upper surface SBa and the lower surface SBb of the substrate SB. Specifically, after forming the plurality of through holes VH, the buffer layer BL may first be formed on the side walls VHS of the through holes VH and on the upper surface SBa and the lower surface SBb of the substrate SB. The buffer layer BL may have a single-layer structure or a multi-layer structure and may include organic materials and/or inorganic materials. The organic materials may include, for example, polyimide (PI), poly-p-xylylene (also referred to as parylene), benzocyclobutene (BCB), epoxy, polycarbonate (PC), polyethylene terephthalate (PET), polyethylene naphthalate (PEN), polymers, or other suitable materials. The inorganic materials may include, for example, metals, metal alloys, oxides, nitrides, suitable ceramic materials, other suitable inorganic materials, or combinations thereof, but not limited herein. After forming the buffer layer BL, the seed layer M0 may be formed on the buffer layer BL, and the seed layer M0 may extend into the through holes VH. The seed layer M0 may facilitate the formation of the conductive layer M1 and/or improve adhesion between layers, and the seed layer M0 may have a single-layer structure or a multi-layer structure. The material of the seed layer M0 may include, for example, titanium (Ti), titanium nitride (TiN), ruthenium (Ru), tantalum (Ta), silver (Ag), copper (Cu), or combinations of the above material. After forming the seed layer M0, Step S400 may be performed to form the conductive layer M1 on the seed layer M0 and fill the through holes VH. After forming the conductive layer M1, a partial removal step may be performed to remove portions of the conductive layer M1 disposed outside the through holes VH and portions of the seed layer M0, so that portions of the stacked layer structure located on the upper surface SBa and the lower surface SBb of the substrate SB are removed and the buffer layer BL is exposed. Subsequently, a patterned insulating layer I1 may be formed on the upper surface SBa and the lower surface SBb of the substrate SB. The insulating layer I1 may cover the buffer layer BL and expose the surface of the conductive layer M1 away from the substrate SB. The substrate SB, the buffer layer BL, the seed layer M0, the conductive layer M1, and the insulating layer I1 may together constitute a substrate structure SBS as shown in FIG. 4, which may be applied in an electronic device (e.g., an electronic device ED shown in FIG. 9) as part of a stacked layer structure of the electronic device. The material of the insulating layer I1 may include, for example, polyimide, photosensitive polyimide (PSPI), Ajinomoto build-up film (ABF), silicon oxide (SiOx), silicon nitride (SiNx), silicon oxide nitride (SiOxNy), or other suitable dielectric materials. In some embodiments, after any of the above process steps, an inspection step may be performed on the formed structure using the first equipment EP shown in FIG. 3, and the inspection step may include providing light to pass through the substrate SB and the stacked layer structure formed on the substrate SB, so as to obtain a phase difference and calculate a stress value corresponding to the structure. During each inspection step, the substrate SB may be heated to different temperatures. For example, the inspection step may be performed after forming the buffer layer BL, after the step of removing the portions of the conductive layer M1, and/or after forming the insulating layer I1. The detailed steps of the inspection step may be referred to the aforementioned first inspection step and second inspection step, and will not be repeated herein.

In some embodiments, then Step S500 may be performed to form a circuit structure. After performing Step S500, Step S510 may be performed to conduct a fourth inspection step on the substrate SB by the first equipment EP shown in FIG. 3. The fourth inspection step may include providing a fourth light to pass through the substrate SB, the conductive layer M1, and/or the circuit structure, so as to obtain a fourth phase difference and calculate a fourth stress value. During the fourth inspection step, the substrate SB and the stacked layer structure formed thereon may have a fourth temperature, wherein the fourth temperature may be different from the first temperature, the second temperature and the third temperature. The wavelength of the fourth light may be the same as or different from the wavelengths of the first light, the second light, and the third light. The detailed steps of the fourth inspection step may be referred to the aforementioned first inspection step and second inspection step.

According to the embodiments shown in FIG. 1 to FIG. 5, the manufacturing method of the electronic device of the present disclosure includes performing inspection on the substrate SB respectively after the laser modification step, the perforation step, and/or any other process step, so that the stress value of the substrate SB may be obtained in real time for quality control, thereby improving product yield. Furthermore, before performing inspection on the substrate SB, the substrate SB may be heated to a specific temperature, so that the stress value of the substrate SB at the specific temperature may be detected.

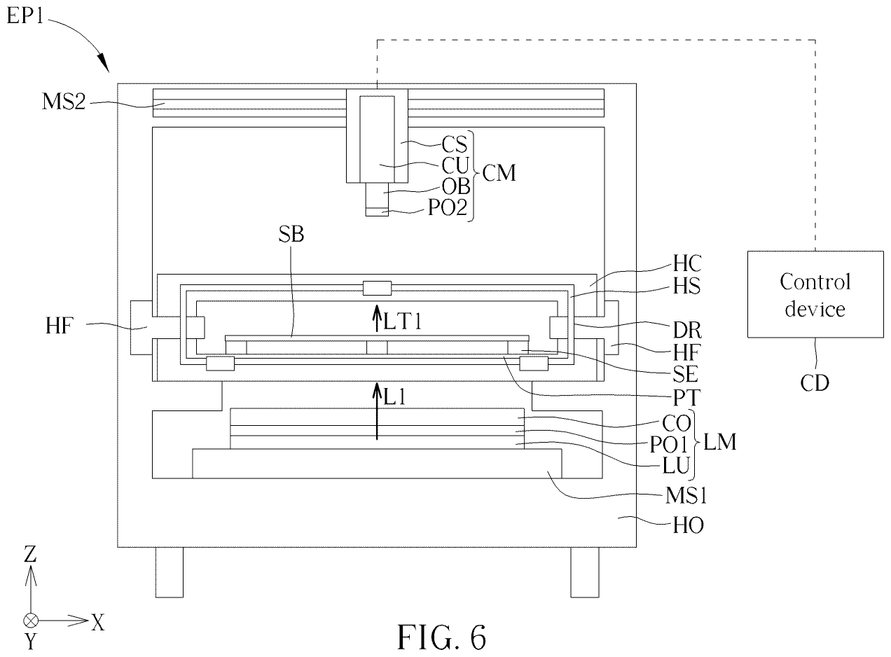

Please refer to FIG. 6, which is a schematic diagram illustrating the architecture of a first equipment according to another embodiment of the present disclosure. The first equipment EP1 shown in FIG. 6 is different from the first equipment EP shown in FIG. 3 in that the first equipment EP1 may include a heater fan module HF for heating, which may replace the ceramic heating plate module HM and the fan module FM shown in FIG. 3, so as to heat the substrate SB during the inspection step. The heater fan module HF may, for example, heat the substrate SB to a temperature ranging from 25° C. to 500° C., but not limited herein. For instance, in Step S210 and Step S310, the substrate SB may be heated to the first temperature and the second temperature by the heater fan module HF.

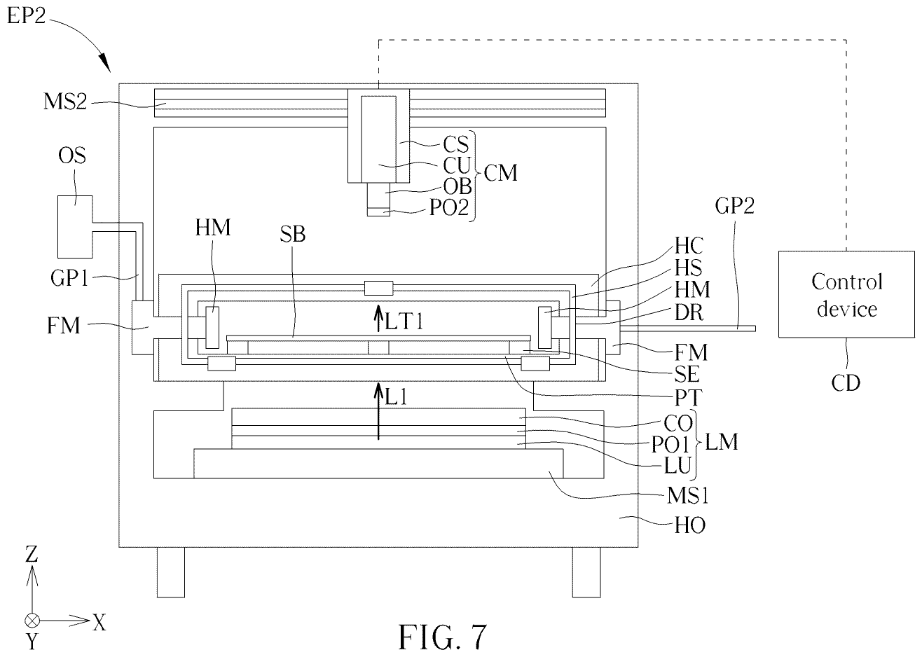

Please refer to FIG. 7, which is a schematic diagram illustrating the architecture of a first equipment according to yet another embodiment of the present disclosure. The first equipment EP2 shown in FIG. 7 is different from the first equipment EP shown in FIG. 3 in that the first equipment EP2 further includes an oxygen detector OS, which may be connected to the heating chamber HC. For example, the oxygen detector OS may be in fluid communication with the heating chamber HC via a first gas channel GP1, but not limited herein. According to the embodiment shown in FIG. 7, during the inspection step, before heating the substrate SB, the oxygen concentration inside the heating chamber HC may be detected by the oxygen detector OS to determine whether the oxygen concentration meets a criterion, such as being less than 20 parts per million (ppm), less than 10 ppm, or less than 5 ppm. By monitoring the oxygen concentration inside the heating chamber HC, the likelihood of oxidation occurring in the stacked layer structure (e.g., the conductive layer M1) on the substrate SB during the heating step may be reduced. In some embodiments, when the oxygen concentration inside the heating chamber HC is less than 20 ppm, the substrate SB may be heated. In some embodiments, before heating the substrate SB or before detecting the oxygen concentration inside the heating chamber HC, nitrogen gas may be introduced into the heating chamber HC to purge the oxygen therein. For example, as shown in FIG. 7, nitrogen gas may be introduced into the heating chamber HC via a second gas channel GP2 in fluid communication with the heating chamber HC, but not limited herein. In other embodiments, a vacuum pump connected to the heating chamber HC may be used to extract the oxygen from the heating chamber HC, but not limited herein.

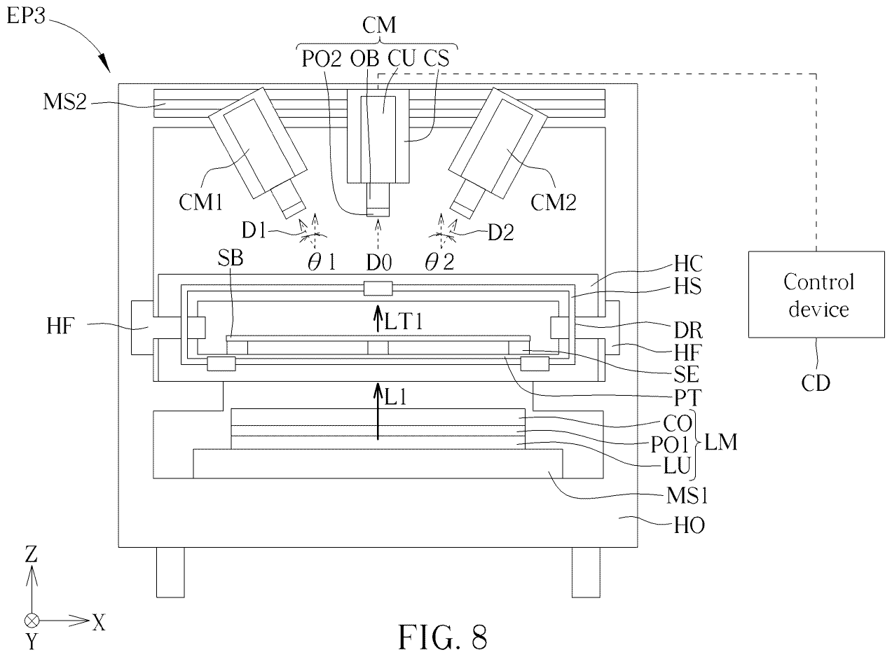

Please refer to FIG. 8, which is a schematic diagram illustrating the architecture of a first equipment according to still another embodiment of the present disclosure. The first equipment EP3 shown in FIG. 8 is different from the first equipment EP1 shown in FIG. 6 in that the first equipment EP3 may further include another camera module CM1 and yet another camera module CM2. That is to say, the first equipment EP3 may include a plurality of camera modules CM to CM2, wherein the orientations of the objectives of the camera modules CM to CM2 may be different, such that the light-receiving directions of the camera modules CM to CM2 may be different. As shown in FIG. 8, an included angle θ1 between a light-receiving direction D1 of the camera module CM1 and the direction Z may be different from an included angle between a light-receiving direction DO of the camera module CM and the direction Z (which is 0 and not labeled in FIG. 8). Furthermore, an included angle θ2 between a light-receiving direction D2 of the camera module CM2 and the direction Z may be different from the included angle between the light-receiving direction DO of the camera module CM and the direction Z. During the inspection step (e.g., Steps S210 to S510), the camera modules CM to CM2 may receive inspection light from different angles to monitor stress induced by different angles.

Please refer to FIG. 9, which is a cross-sectional schematic diagram of an electronic device according to an embodiment of the present disclosure. The electronic device ED shown in FIG. 9 is merely an example, and the structure of the electronic device of the present disclosure is not limited thereto. As shown in FIG. 9, the electronic device ED manufactured by the method of the present disclosure may include a substrate SB, a buffer layer BL, a seed layer M0, a conductive layer M1, and an insulating layer I1. The electronic device ED may further include a circuit structure CST disposed on one side of the substrate SB and disposed on the conductive layer M1 and the insulating layer I1. The substrate SB may include one or more through holes VH and may optionally include a marking element MK. Each through hole VH penetrates the substrate SB, and the marking element MK may be used to provide an alignment function. The side wall VHS of the through hole VH may connect the upper surface SBa and the lower surface SBb of the substrate SB. The buffer layer BL may cover the upper surface SBa and the lower surface SBb of the substrate SB as well as the side walls VHS of the through holes VH. The seed layer M0 may be disposed on the side walls VHS of the through holes VH and disposed on a portion of the surface of the buffer layer BL. The conductive layer M1 may be disposed on the surface of the seed layer M0 and fill the through holes VH, thereby forming conductive elements. The insulating layer I1 may be disposed on the upper surface SBa and the lower surface SBb of the substrate SB, and the insulating layer I1 may cover the buffer layer BL while exposing the surface of the conductive layer M1 that is away from the substrate SB. The detailed structures and materials of the above-mentioned layers and elements of the electronic device ED may be referred to the aforementioned embodiments.

According to the embodiment shown in FIG. 9, the circuit structure CST, which may be a fan-out structure, may include at least one conductive layer (e.g., one or more conductive layers CL) and at least one insulating layer (e.g., one or more insulating layers IL). Each insulating layer IL may include at least one opening such that the conductive layer M1 in the through holes VH of the substrate SB is electrically connected to the conductive layers CL in the stacking direction, wherein the stacking direction referred to in the present disclosure may be the direction Z. The conductive layer CL farthest from the substrate SB may include a plurality of pads for bonding with an electronic unit EU or other suitable components. One or more electronic units EU may be disposed on and bonded to the circuit structure CST via bonding elements CE1, such that the electronic unit EU may be electrically connected to other components through the conductive layers CL and the conductive layer M1 in the through holes VH of the substrate SB. For example, the electronic unit EU may be further electrically connected to a circuit board CB via bonding elements CE2 disposed on one side of the substrate SB opposite to the circuit structure CST. The bonding elements CE1 and CE2 may include, for example, solder balls, nickel, gold, copper, gallium, or other suitable conductive materials. The insulating layer IL may be similar to the insulating layer I1. The conductive layer CL may include conductive materials similar to those of the conductive layer M1.

As shown in FIG. 9, the electronic device ED may further include a protective layer PRL surrounding the substrate SB, the circuit structure CST and the electronic units EU, for isolating moisture, air, and/or reducing damage to the electronic units EU. The material of the protective layer PRL may include organic resin, epoxy molding compound (EMC), ceramic, other suitable materials, or combinations thereof, but not limited herein. In some embodiments, the electronic device ED may further include a filling layer FL1 and a filling layer FL2. The filling layer FL1 may be disposed between the electronic unit EU and the circuit structure CST to surround and protect the bonding elements CE1, and the filling layer FL2 may be disposed between the substrate SB and the circuit board CB to surround and protect the bonding elements CE2 and may serve as a buffer layer, but not limited herein.

Please refer to FIG. 10, which is a cross-sectional schematic diagram of an electronic device according to another embodiment of the present disclosure. As shown in FIG. 10, an electronic device ED1 of this embodiment is different from the electronic device ED shown in FIG. 9 in that the circuit board CB is replaced with a circuit board CB1, and the circuit board CB1 may include a core substrate 100, a circuit structure 200 and a circuit structure 300, wherein the circuit structure 200 and the circuit structure 300 are respectively disposed on the upper side and the lower side of the core substrate 100. In addition, the buffer layer BL may only cover the side walls VHS of the through holes VH, and the upper surface SBa and the lower surface SBb of the substrate SB are not covered by the buffer layer BL. The electronic device ED1 does not include the insulating layer I1. The electronic device ED1 of this embodiment may further include an electronic unit EU1, an electronic unit EU2, a plurality of bonding elements CE3, a protective layer 400, an encapsulation layer 410, an adhesive layer 420 and a heat dissipation element 500.

According to the embodiment shown in FIG. 10, the core substrate 100 may include a substrate 110, a buffer layer 120 and a plurality of conductive elements 130. The substrate 110 may include sub-substrates 111 and 112 stacked sequentially. The substrate 110 may have a plurality of through holes VH1, each of the through holes VH1 may be formed by a sub-through hole VH11 in the sub-substrate 111 and a sub-through hole VH12 in the sub-substrate 112. A side wall VH1S of the through hole VH1 may connect an upper surface 110a and a lower surface 110b of the substrate 110. In some embodiments, the substrate 110 may include more than two sub-substrates stacked sequentially. The thermal expansion coefficient and thickness of any two sub-substrates may be the same or different form each other. For example, the thermal expansion coefficient of the sub-substrate 111 may be different from that of the sub-substrate 112, such as being smaller than that of the sub-substrate 112. The thickness of the substrate 110 may be greater than that of the substrate SB. The material of the substrate 110 may be similar or identical to that of the substrate SB, and will not be repeated herein. In some embodiments, the light transmittance of the substrate 110 may be different from that of the substrate SB. For example, the substrate 110 may have a higher transmittance to white light than the substrate SB. In some embodiments, corners CR1 of the substrate 110 and corners CR2 of the substrate SB may respectively have rounded corners or chamfers. The buffer layer 120 may partially cover the substrate 110. As shown in FIG. 10, the buffer layer 120 may cover the side walls VH1S of the middle two through holes VH1. The conductive elements 130 may be disposed in the through holes VH1, and the buffer layer 120 may surround the conductive elements 130. The conductive elements 130 may be single-layer or multi-layer structures. In some embodiments, the conductive elements 130 may further include a seed layer.

As shown in FIG. 10, the circuit structure 200 may include at least one conductive layer CL2 and at least one insulating layer IL2, and the circuit structure 300 may include at least one conductive layer CL3 and at least one insulating layer IL3. The topmost conductive layer CL2 in the circuit structure 200 may be electrically connected to the bonding elements CE2. The conductive elements 130 in the through holes VH1 of the substrate 110 may be electrically connected to the conductive layers CL2 and CL3 in the stacking direction Z via at least one via in the insulating layers. The plurality of bonding elements CE3 may be disposed on the surface of the conductive layer CL3 farthest from the substrate 110 in the circuit structure 300, for bonding with other components. The protective layer 400 may be disposed on the surface 300S of the circuit structure 300 that is away from the core substrate 100. A portion of the protective layer 400 may be disposed in the gaps between the bonding elements CE3 to prevent moisture or contamination from entering the circuitry of the circuit structure 300, and may also be used to define the size of the bonding elements CE3. The materials of the conductive layers CL2 and CL3 may be referred to those of the conductive layer CL in the aforementioned embodiments. The materials of the insulating layers IL2 and IL3 may be referred to those of the insulating layer IL in the aforementioned embodiments. The material of the bonding elements CE3 may be referred to those of the bonding elements CE1 and CE2 in the aforementioned embodiments.

The electronic unit EU1 may be disposed within the substrate 110 of the core substrate 100. For example, a recessed space RS1 may be formed in the substrate 110 to accommodate the electronic unit EU1, and the electronic unit EU1 is electrically connected to the conductive layer CL2 in the circuit structure 200. Accordingly, the electronic unit EU1 may be electrically connected to the electronic unit EU through the circuit structure 200 and the bonding elements CE2, and the electronic unit EU1 may further be electrically connected to other external components (not shown) through the circuit structure 200, the conductive elements 130, the circuit structure 300 and the bonding elements CE3. The electronic unit EU2 may be disposed within the substrate SB. For example, a recessed space RS2 may be formed in the substrate SB to accommodate the electronic unit EU2, and the electronic unit EU2 is electrically connected to the conductive layer M1. Accordingly, the electronic unit EU2 may be electrically connected to the electronic unit EU through the conductive layer M1 and the conductive layer CL2, and the electronic unit EU2 may further be electrically connected to the circuit structure 200 through the conductive layer M1 and the bonding elements CE2.

The heat dissipation element 500 may be configured to provide a heat dissipation function. The heat dissipation element 500 is disposed on the circuit board CB1 and surrounds the substrate SB, the circuit structure CST and the electronic units EU. Atop cover portion 510 of the heat dissipation element 500 is disposed on the upper surface of the electronic unit EU and may directly contact the upper surface of the electronic unit EU, and a side wall portion 520 thereof surrounds and directly contacts the encapsulation layer 410. The material of the heat dissipation element 500 may include, for example, metal, silicon, silicon carbide, graphite, graphene, other suitable materials, or combinations thereof, but not limited herein. The encapsulation layer 410 may be disposed in the space between the protective layer PRL, the filling layer FL2 and the heat dissipation element 500. The material of the encapsulation layer 410 may be referred to that of the protective layer PRL in the aforementioned embodiments, and may be the same as or different from the material of the protective layer PRL.

The adhesive layer 420 may be disposed between the heat dissipation element 500 and the surface 200S of the circuit structure 200. The heat dissipation element 500 may be fixed to the circuit board CB1 through the adhesive layer 420. In some embodiments, a surface treatment process may be performed on the surface 200S of the circuit structure 200 to roughen the surface, thereby enhancing the bonding strength between the adhesive layer 420 and the surface 200S. The material of the adhesive layer 420 may include acrylic resin, urethane resin, other suitable materials, or combinations thereof, but not limited herein. In some embodiments, a thermal adhesive material may be selected for the adhesive layer 420 to provide a heat dissipation function.

From the above description, according to the manufacturing method of the electronic device and the electronic device manufactured thereby in the embodiments of the present disclosure, inspection may be performed on the substrate respectively after the laser modification step, the perforation step, and/or any other process step, so that the stress value of the substrate may be obtained in real time for quality control, thereby improving product yield. Furthermore, before performing inspection on the substrate, the substrate may be heated to a specific temperature, so that the stress value of the substrate at the specific temperature may be detected. In addition, during the inspection step, the oxygen concentration inside the heating chamber may further be monitored to reduce the likelihood of oxidation occurring in the stacked layer structure on the substrate during heating.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate;
performing a laser modification step on the substrate to form a plurality of modified regions;
performing a first inspection step on the substrate by a first equipment after the laser modification step, wherein the first inspection step comprises providing a first light to pass through the substrate, so as to obtain a first phase difference and calculate a first stress value;
performing a perforation step on the substrate to form a plurality of through holes in the plurality of modified regions; and
performing a second inspection step on the substrate by the first equipment after the perforation step, wherein the second inspection step comprises providing a second light to pass through the substrate, so as to obtain a second phase difference and calculate a second stress value,
wherein the substrate has a first temperature during the first inspection step, the substrate has a second temperature during the second inspection step, and the second temperature is different from the first temperature.

2. The manufacturing method of the electronic device according to claim 1, wherein the first inspection step further comprises placing the substrate on a platform of the first equipment and heating the substrate to the first temperature before providing the first light.

3. The manufacturing method of the electronic device according to claim 2, wherein the second inspection step further comprises placing the substrate on the platform of the first equipment and heating the substrate to the second temperature before providing the second light.

4. The manufacturing method of the electronic device according to claim 2, wherein the first inspection step further comprises: monitoring whether a temperature of the substrate reaches the first temperature by the first equipment, and providing the first light to pass through the substrate when the temperature of the substrate reaches the first temperature.

5. The manufacturing method of the electronic device according to claim 2, wherein the platform is movable along a first direction, and the first direction is perpendicular to a normal direction of the substrate.

6. The manufacturing method of the electronic device according to claim 1, wherein the first light and the second light are individually selected from visible light having a wavelength of 360 nm to 830 nm, near-infrared light having a wavelength of 700 nm to 1400 nm, short-wave infrared light having a wavelength of 1400 nm to 3000 nm, mid-wave infrared light having a wavelength of 3000 nm to 5000 nm, or long-wave infrared light having a wavelength of 8 μm to 12 μm.

7. The manufacturing method of the electronic device according to claim 1, wherein the first inspection step comprises:
enabling the first light to pass through a first polarizer and then through the substrate to form a first inspection light; and
enabling the first inspection light to pass through a second polarizer to obtain the first phase difference.

8. The manufacturing method of the electronic device according to claim 7, wherein the second inspection step comprises:
enabling the second light to pass through the first polarizer and then through the substrate to form a second inspection light; and
enabling the second inspection light to pass through the second polarizer to obtain the second phase difference.

9. The manufacturing method of the electronic device according to claim 1, further comprising:
forming a conductive layer in the plurality of through holes; and
performing a third inspection step on the substrate by the first equipment after forming the conductive layer, wherein the third inspection step comprises providing a third light to pass through the substrate, so as to obtain a third phase difference and calculate a third stress value,
wherein the substrate has a third temperature during the third inspection step, and the third temperature is different from the first temperature and the second temperature.

10. The manufacturing method of the electronic device according to claim 1, wherein the first equipment comprises a heating chamber, a light-emitting module and a camera module, and the light-emitting module and the camera module are disposed on two opposite sides of the heating chamber, wherein the first inspection step comprises:
placing the substrate in the heating chamber and heating the substrate to the first temperature;
enabling the light-emitting module to provide the first light such that the first light passes through the substrate to form a first inspection light; and
receiving the first inspection light by the camera module to obtain the first phase difference.

11. The manufacturing method of the electronic device according to claim 10, wherein the second inspection step comprises:
placing the substrate in the heating chamber and heating the substrate to the second temperature;
enabling the light-emitting module to provide the second light such that the second light passes through the substrate to form a second inspection light; and
receiving the second inspection light by the camera module to obtain the second phase difference.

12. The manufacturing method of the electronic device according to claim 10, wherein a refractive index of the heating chamber is greater than or equal to 1.4 and less than or equal to 1.6.

13. The manufacturing method of the electronic device according to claim 12, wherein the refractive index of the heating chamber is equal to a refractive index of the substrate.

14. The manufacturing method of the electronic device according to claim 10, wherein the light-emitting module comprises a first polarizer, and the camera module comprises a second polarizer.

15. The manufacturing method of the electronic device according to claim 10, wherein the first equipment further comprises an oxygen detector connected to the heating chamber, and the manufacturing method of the electronic device further comprises detecting an oxygen concentration inside the heating chamber by the oxygen detector before heating the substrate.

16. The manufacturing method of the electronic device according to claim 15, wherein the substrate is heated when the oxygen concentration is less than 20 parts per million.

17. The manufacturing method of the electronic device according to claim 10, further comprising introducing nitrogen gas into the heating chamber before heating the substrate.

18. The manufacturing method of the electronic device according to claim 10, wherein the heating chamber and the light-emitting module are movable along a first direction, and the first direction is perpendicular to a normal direction of the substrate.

19. The manufacturing method of the electronic device according to claim 18, wherein the camera module is movable along a second direction, and the second direction is perpendicular to both the first direction and the normal direction of the substrate.

20. The manufacturing method of the electronic device according to claim 18, wherein the first equipment further comprises another camera module, and an included angle between a light-receiving direction of the another camera module and the normal direction of the substrate is different from an included angle between a light-receiving direction of the camera module and the normal direction of the substrate.
